(19) United States
(12) Patent Application Publication
(10) Pub. No.: US 2022/0368114 A1
(43) Pub. Date: Nov. 17, 2022

(54) SWITCH CABINET WITH A CLOSING ELEMENT PRETENSIONED INTO AN OPEN POSITION

(71) Applicant: RITTAL GMBH & CO. KG, Herborn (DE)

(72) Inventors: Sven Michael LAURÖSCH, Haiger (DE); Frank PHILIPP, Bad Marienberg (DE); Carsten BÄUMER, Freudenberg (DE)

(21) Appl. No.: 17/767,086

(22) PCT Filed: Aug. 28, 2020
(86) PCT No.: PCT/DE2020/100763

§ 371 Date: Apr. 7, 2022

(30) Foreign Application Priority Data
Oct. 11, 2019 (DE) 10 2019 127 470.2

(51) Int. Cl. H02B 1/38; H02B 1/30

(52) U.S. Cl. CPC H02B 1/38; H02B 1/306

(57) ABSTRACT

The invention relates to a switch cabinet having a housing and a door which is pivotally secured thereto via at least one hinge and has a door leaf, wherein the door leaf has an aperture and a closing element which closes the aperture and is held in a closed position, counter to its mechanical pretension in the direction of its open position, by an electrically controllable locking element.

### CROSS-REFERENCE TO RELATED APPLICATIONS

This application is a U.S. National Phase Application under 35 U.S.C. 371 of International Application No. PCT/DE2020/100763, filed on Aug. 28, 2020, which claims the benefit of German Patent Application No. 10 2019 127 470.2, filed on Oct. 11, 2019. The entire disclosures of the above applications are incorporated herein by reference.

### BACKGROUND

This section provides background information related to the present disclosure which is not necessarily prior art.

Technical Field

The invention is based on a switch cabinet having a housing and a door having a door leaf, the door being pivotally secured thereto via at least one hinge and being held in a closed position against a mechanical pretension in the direction of its open position by an electrically controllable locking element. Such a switch cabinet is known from CN 109119914 A. DE 10 2006 010 360 B3 describes a similar switch cabinet.

Discussion

In particular, such switchgear cabinets are set up to enable emergency ventilation of the interior of the switchgear cabinet in the event of an emergency, for example in the event of a failure of the cooling system of the electrical switchgear, IT environment or the like accommodated in the switchgear cabinet housing, in order, for example, to at least delay a server failure so that time is gained to initiate measures that either restore the normal operating state of the switchgear cabinet or to properly shut down the switchgear or, in particular, an IT environment so that destruction of the system is avoided.

In order to mechanically pretension the switch cabinet door into the open position, suitable pretensioning means are used, for example gas springs. This has the disadvantage that after a regular opening of the switch cabinet door, for example to perform maintenance on the equipment or IT environment housed in the switch cabinet, a considerable force must be applied by a user to overcome the pretension of the closing element when the switch cabinet is closed again. In addition, the principles of the system dictate that standardized enclosure closure systems cannot be used, such as push rod closures, which counteracts the desire to use common parts. In addition, the known switch cabinets have the disadvantage that, for example, in an emergency, doors opened fully automatically by electrically controlling the locking element allow unhindered access to the interior of the switch cabinet, which may be undesirable not only for reasons of data protection.

### SUMMARY

This section provides a general summary of the disclosure, and is not a comprehensive disclosure of its full scope or all of its features.

It is therefore one aspect of the invention to further develop a switch cabinet of the type described at the beginning in such a way that it avoids the application of high closing forces when closing the switch cabinet door, moreover, it dispenses with the use of special closures for the switch cabinet door and, moreover, it is prepared to provide access protection to the interior of the switch cabinet if necessary when the switch cabinet is in an emergency-opened state.

Accordingly, it is provided that the door leaf has an aperture and a closing element closing the aperture, which is held in a closed position against its mechanical pretension in the direction of its open position by an electrically controllable locking element.

The fact that the entire switch cabinet door does not have to be opened for emergency ventilation of the switch cabinet enclosure means, on the one hand, that during normal operation of the switch cabinet system, a user can open and close the switch cabinet door without having to apply a high closing force, as he no longer has to work against the pretensioning force of the emergency opening. In addition, the switch cabinet door closing system can also be designed as in a standard switch cabinet without emergency ventilation, for example as a push-rod lock that is adjustable via a toggle door handle. Finally, the solution according to the invention allows suitable measures to be provided on the inside of the door leaf to prevent access to the interior of the switch cabinet when the closing element is in an open position with the switch cabinet door closed. For this purpose, for example, an access protection grille, such as a perforated grille, can be provided to close off the opening from the inside of the door leaf. During normal operation, in which the user opens the switch cabinet door for maintenance purposes, for example, the access protection does not prevent the user from gaining access to the interior of the switch cabinet. An access authorization query can be made via the door handle of the switch cabinet door, as in standard switch cabinets, for example via a cylinder lock or a wireless interface for reading an access authorization card.

The pretensioning in the direction of the open position can be provided by at least one compression spring extending in the aperture, preferably by a gas compression spring.

The closing element may be a door having at least one door leaf, preferably two door leaves, which is/are pivotally fixed to a vertical edge of the aperture via at least one further hinge. Accordingly, in one embodiment, the switch cabinet door according to the invention may be designed as a door-in-door concept. It may be provided that the aperture extends over a major part of the height and the width of the door leaf, in order to provide the largest possible opening cross-section for the exchange of air. Preferably, the aperture extends over at least 50% of the height and/or width of the door leaf.

It may be provided that the aperture extends in one piece over a major part of the height of the door leaf, but at least over 50% of the height. It may also be provided that the opening is divided in two in the width direction over a vertical central web of the door leaf, while it is preferably uninterrupted in the height direction.

The electrically controllable guard locking element can have at least one electromagnet that projects into the clear opening of the door panel on an inner side of the door panel over a border of the opening.

The pretensioning in the direction of the open position can be provided, at least in a first partial movement section of the closing element from the closed position in the direction of the open position, by a redundant pretensioning device with at least two pretensioning elements designed independently of one another.

In this context, a first of the preloading elements may comprise a compression spring, preferably a gas compression spring, and a second of the preloading elements may comprise an elastically deformable spring element, preferably a helical spring.

One of the two redundant pretensioning elements can be disengaged from the closing element and the other can continue to be engaged with the closing element when the closing element is arranged outside the first movement section in a partially opened position between the open position and the closed position. In this way, it is possible that when the electrically controllable locking element is triggered, i.e. released, along the first partial movement section of the locking element from the closed position, an increased torque is applied to the locking element to achieve rapid movement of the locking element out of the closed position.

The opening can be covered by an air-permeable access protection grille on an inner side of the door leaf facing the interior of the switch cabinet. The at least one closing element closing the opening can have at least one door leaf that can be pivoted from the closed position to the outside of the door leaf in the direction of the open position.

The door of the switch cabinet can be moved back and forth without tension between a fully open position and a fully closed position, in which the door leaf rests on the frame of the switch cabinet via a sealing element, and can be locked in the closed position with a push rod lock on the frame while compressing the sealing element, so that in normal operation, i.e. in an operating situation in which emergency ventilation of the switch cabinet has not been triggered, there is no operating difference for a user compared to a standard switch cabinet which has no emergency ventilation. i.e. in an operating situation in which emergency ventilation of the switch cabinet has not been triggered, there is no difference in operation for a user compared to a standard switch cabinet which has no emergency ventilation.

The door of the switch cabinet may have two opposing partial doors hinged to opposite vertical profile sides of the housing, each of which has a door leaf forming the closing element, which is pivotally fixed to an outer one of the two vertical edges of the aperture via at least one further hinge.

Alternatively, the door of the switch cabinet may be a door hinged to a vertical profile side of the housing and having two door leaves forming the closing element, the door leaves being pivotable in the same direction, for which purpose a first one of the door leaves is pivotally secured to an outer one of two vertical edges of the aperture via at least one further hinge and a second one of the door leaves is pivotally secured to a vertical central web of the door leaf bisecting the aperture via at least one further hinge.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

Further details of the invention are explained with reference to the figures below. Thereby:

FIG. 1 shows a generic switch cabinet according to the state of the art;

FIG. 2 shows a front view of an exemplary embodiment of a switch
cabinet door according to the invention;

FIG. 3 shows a perspective view of the switch cabinet door according to
FIG. 2 with the closing element open;

FIG. 4 shows a detailed view of a horizontal cross-section through a
further embodiment of a switch cabinet according to the invention;

FIG. 5 shows the embodiment according to FIG. 4 in a partially opened
state of the closing element; and

FIG. 6 shows a detailed view of a further embodiment of a switch cabinet
door according to the invention with the closing element open.

### DETAILED DESCRIPTION

Example embodiments will now be described more fully with reference to the accompanying drawings.

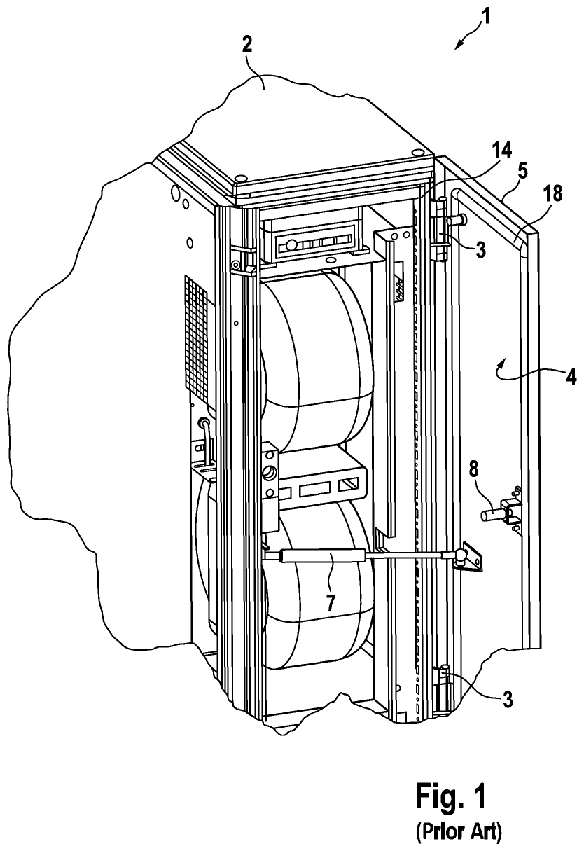

FIG. 1 shows a section of a switch cabinet 1 as known from the prior art and described in full detail in DE 10 2016 010 360 B3.

The switch cabinet 1 has a frame 14 to which various flat parts are fixed, for example a side panel, a roof panel and in particular the rear door 5, which in the embodiment according to FIG. 1 is in an open state, is provided on a rear side of the switch cabinet 1 and is designed for emergency opening in the event of an accident, for example in order to provide emergency ventilation of the switch cabinet interior if the switch cabinet cooling system fails.

For emergency ventilation, the switch cabinet door 5 is pretensioned into its open position shown in FIG. 1 by a closing element 7 designed as a gas pressure spring, while a locking element 8 designed, for example, as a magnetic lock is set up to keep the switch cabinet door in a closed state during regular operation of the switch cabinet system, i.e. i.e. in any case where the emergency ventilation of the switch cabinet interior shown in FIG. 1 is not required, to keep the rear panel door 5 in a closed state, for which purpose the locking element 8 must provide a closing force which counteracts the pretensioning into the open position provided by the gas pressure spring 7, i.e. at least compensates for it and preferably significantly overcompensates for it.

The embodiment according to FIG. 1 illustrates that, for example, in the event of maintenance, a user who has opened the rear door 5 is not only prevented by the gas spring 7 from gaining trouble-free access to the interior. After maintenance has been performed, the user must overcome the pretensioning force of the gas spring to move the door 5 to its closed position in order to reclose the rear door 5. After he has moved the door 5 into the closed position with the appropriate amount of force, he must activate the locking element 8, for example a magnetic lock, so that the door 5 is held in the closed position against the pretension of the gas pressure spring 7. Furthermore, FIG. 1 shows that in the event that the locking element 8 has been triggered and the door 5 has subsequently been opened, any possibly unauthorized third party has access to the interior of the switch cabinet 1.

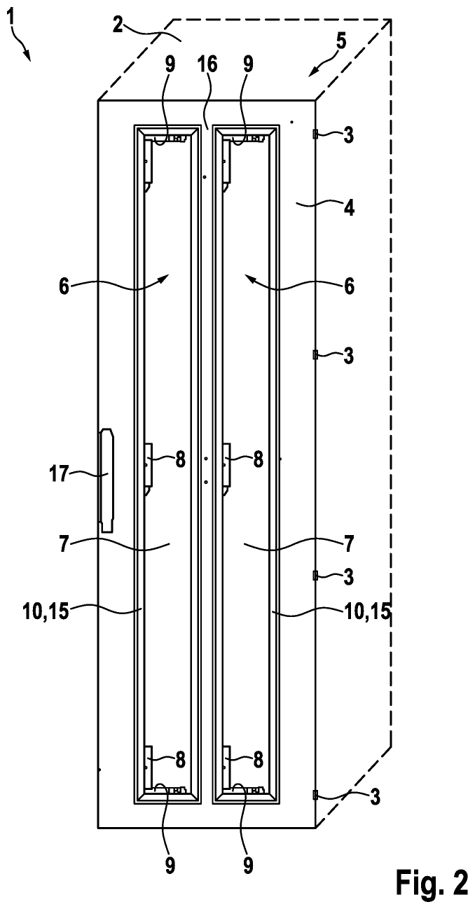

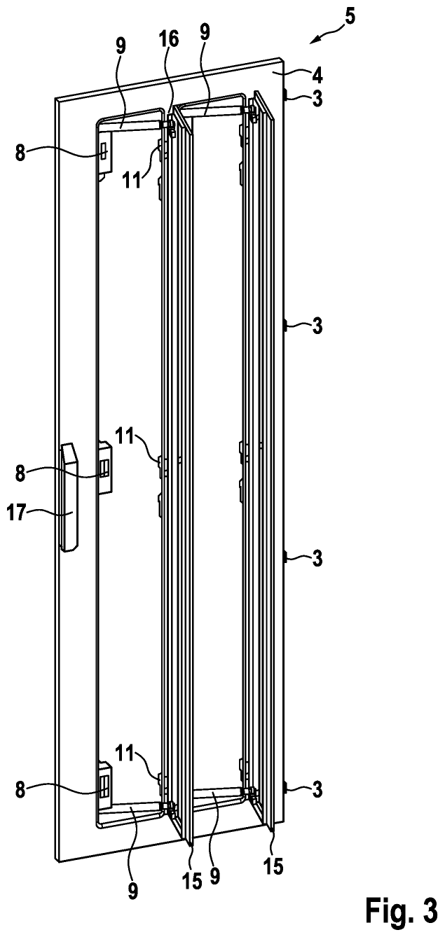

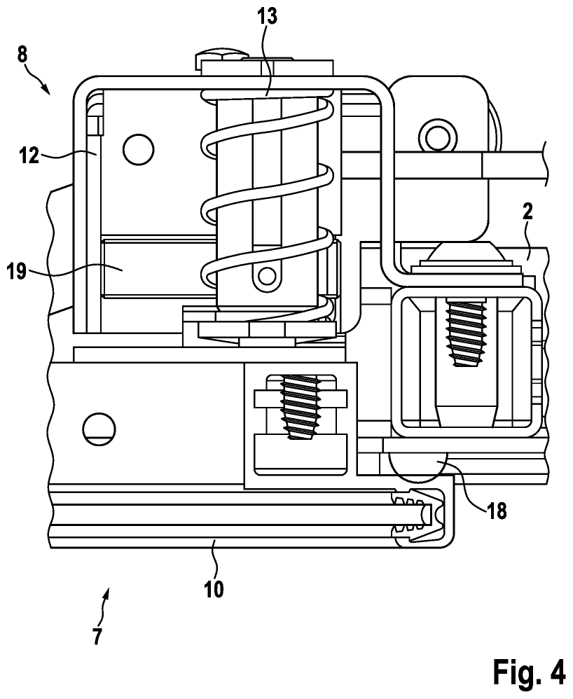

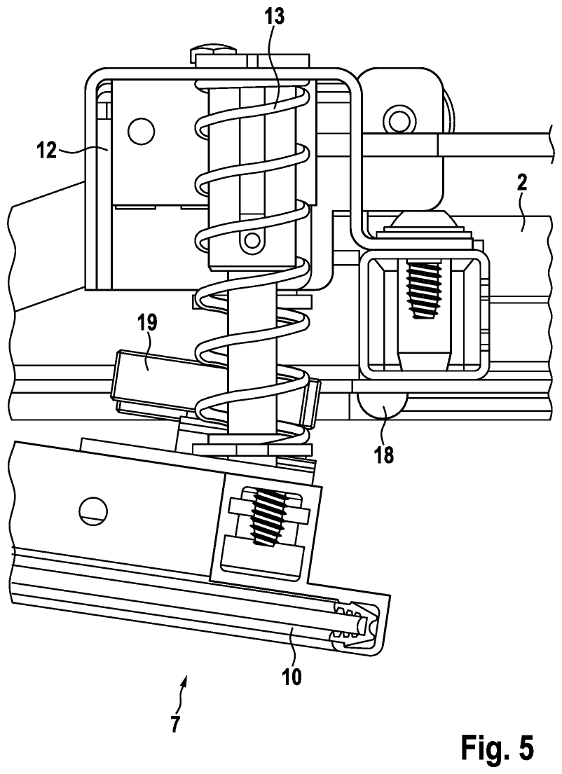

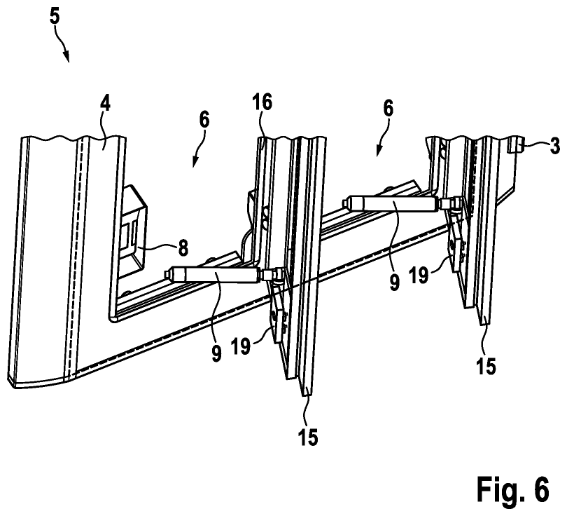

In contrast, FIG. 2 illustrates an exemplary embodiment of a switch cabinet door 5 according to the invention, which has a door leaf 4, which has a row of equidistant hinges 3 or hinge halves on the door side on opposite vertical sides and, on the other hand, a push rod lock 17 on the opposite vertical side, which can be adjusted by means of a toggle lever mounted on the front side of the door leaf 4. In this respect, the switch cabinet door 5 is designed like a standard switch cabinet door, which is not prepared for emergency ventilation, so that the use of identical parts is also possible in this respect.

According to the invention, the switch cabinet door 5 has an aperture 6, which in the present case is formed in two parts via a vertical web 16 and extends essentially over the entire or approximately the entire height of the door leaf 4. In the width direction of the door 5 perpendicular to the height, the opening 6 has a width which corresponds to at least more than 50% of the width of the door leaf 4. Accordingly, the closing element 7 has two door leaves 10, which are each designed as partial doors 15 hinged on one side.

The partial doors 15 are held in the closed position shown in FIG. 2 on their vertical side opposite the hinge side by means of three locking elements 8 arranged vertically and equidistantly one below the other, which may be magnetic locks, for example. On a lower side and on an upper side of the partial doors 15, a gas pressure spring 9 is provided for each partial door 15, which are in a compressed position in the position of the door shown in FIG. 2 and accordingly exert a pretension on the partial doors 15 in the direction of the open position shown in FIG. 3. The locking elements 8 overcome this pretension and hold the partial doors 15 in the closed position shown in FIG. 2.

The locking elements 8 are electrically controllable and can be designed, for example, as magnetic locks which, as shown in FIGS. 4 and 5, can have an electromagnet 12 which is attached to the door leaf 4 of the switch cabinet door 5 in such a way that it projects into the aperture 6. In turn, the door leaf 10 of the closing element 7 has a magnetic or magnetizable armature plate so that the door leaf 10 can be held in the closed position shown in FIG. 4 by means of an electrical attractive force provided by the electromagnet 12. In the case of emergency ventilation, the electromagnet can be de-energized so that the magnetic attraction force between the electromagnet 12 and the armature plate 19 is interrupted, whereupon the door leaf 10 is pivoted to its open position due to the pretension exerted on it, as shown in FIG. 5.

In order to exert as high a torque as possible on the door leaf 10 during the transition of the door leaf 10 from the closed position shown in FIG. 4 to the partially opened position of the door leaf 10 shown in FIG. 5, whereby the door leaf 10 quickly reaches the partially opened position shown in FIG. 5, it is provided that, in addition to a gas pressure spring required, for example, for complete opening, an additional pretensioning force is provided with the aid of an elastic pressure spring 13 which, in the present embodiment, is designed as a helical spring. The helical spring also has the function of damping the closing movement of the door leaf 10 generated by the magnetic attraction force when the door leaf is closed again with the electromagnet already activated, thus reducing the risk of jamming, for example.

A further embodiment of a switch cabinet door 5 according to the invention is shown in FIG. 6. In this case, the aperture 6 is again made in two parts and divided into two equally sized partial apertures by a central web 16 extending vertically over the entire height of the aperture 6. Each of the partial apertures can be closed by a separate partial door 15 and, if necessary, opened with the aid of the compression spring 9 when a magnetic attraction force acting on the armature plates 19 from the electromagnets 12 is interrupted.

The features of the invention disclosed in the foregoing description, in the drawing, and in the claims may be essential to the invention either individually or in any combination.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

1-13. (canceled)

14. A switch cabinet comprising a housing and a door which is pivotally secured thereto via at least one hinge, the door having a door leaf, wherein the door leaf has an aperture and a closing element which closes the aperture and is held in a closed position, counter to its mechanical pretension in the direction of its open position, by an electrically controllable locking element, wherein the pretension in the direction of the open position is provided, at least in a first partial movement section of the closing element from the closed position in the direction of the open position, by a redundant pretensioning device having at least two pretensioning elements which are designed independently of one another, and wherein one of the two redundant pretensioning elements is disengaged from the closing element and the other continues to be engaged with the closing element when the closing element is disposed outside the first partial movement section in a partially open position between the open position and the closed position.

15. The switch cabinet according to claim 14, wherein the pretension in the direction of the open position is provided by at least one compression spring extending in the aperture, preferably by a gas compression spring.

16. The switch cabinet according to claim 14, in which the closing element is a door which has at least one door leaf, preferably two door leaves, which is pivotally fixed to a vertical edge of the aperture via at least one further hinge.

17. The switch cabinet according to claim 14, in which the electrically controllable locking element has at least one electromagnet which projects into the clear opening of the aperture on an inner side of the door leaf beyond a border of the aperture.

18. The switch cabinet according to claim 14, wherein a first of said pretensioning elements comprises a compression spring, preferably a gas compression spring, and a second of said pretensioning elements comprises an elastically deformable spring element, preferably a coil spring.

19. The switch cabinet according to claim 14, in which the aperture is covered by an air-permeable access protection grille on an inner side of the door leaf facing the interior of the switch cabinet, the at least one closing element closing the aperture having at least one door leaf which can be pivoted from the closed position towards the outer side of the door leaf in the direction of the open position.

20. The switch cabinet according to claim 14, in which the door of the switch cabinet can be moved back and forth without pretension between a fully open position and a fully closed position, in which the door leaf bears against the frame of the switch cabinet via a sealing element, and in the closed position is locked to the frame with compression of the sealing element by a push rod lock.

21. The switch cabinet according to claim 14, wherein the door of the switch cabinet either
a. has two part doors which move in opposite directions and are hinged to opposite vertical profile sides of the housing, each of which has a door leaf which forms the closing element and is fixed pivotally to an outer one of the two vertical edges of the opening via at least one further hinge; or
b. is a door hinged to a vertical profile side of the housing and having two door leaves forming the closing element, the door leaves being pivotable in the same direction, for which purpose a first one of the door leaves is pivotally secured to an outer one of two vertical edges of the opening via at least one further hinge, and a second one of the door leaves is pivotally secured to a vertical central web of the door leaf, which vertical web bisects the opening, via at least one further hinge.

22. The switch cabinet according to claim 14, wherein the aperture extends over a major part of the height and the width of the door leaf, but at least over more than 50% of the height and the width.

23. The switch cabinet according to claim 14, wherein the aperture extends integrally over a major part of the height of the door leaf, but at least over more than 50% of the height.

24. The switch cabinet according to claim 14, in which the aperture is divided in two in the width direction via a vertical central web of the door leaf, while it is uninterrupted in the height direction.
